(19) United States
(12) Patent Application Publication
(10) Pub. No.: US 2010/0091154 A1
(43) Pub. Date: Apr. 15, 2010

(54) Image Sensor and Method For Manufacturing the Same

(76) Inventors: HEE SUNG SHIM, Gangwon-do (KR); Jae Hyun Yoo, Incheon-si (KR); Jong Min Kim, Seoul (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/575,790

(22) Filed: Oct. 8, 2009

(30) Foreign Application Priority Data
Oct. 14, 2008 (KR) 10-2008-0100582

(51) Int. Cl. H04N 5/335; H01L 21/768

(52) U.S. Cl. 348/294; 438/98; 257/E21.575

(57) ABSTRACT

An image sensor is provided. The image sensor comprises a readout circuitry, an interconnection, an image sensing device and a via plug. The readout circuitry is disposed in a first substrate. The interconnection is disposed over the first substrate and electrically connected to the readout circuitry. The image sensing device is disposed over the interconnection. The via plug is formed at a pixel boundary and electrically connects the image sensing device and the interconnection.

### CROSS-REFERENCE TO RELATED APPLICATION

This application claims the benefit under 35 U.S.C. §119 of Korean Patent Application No. 10-2008-0100582, filed Oct. 14, 2008, which is hereby incorporated by reference in its entirety.

### BACKGROUND

The present disclosure relates to an image sensor and a method for manufacturing the same.

An image sensor is a semiconductor device for converting an optical image into an electric signal. The image sensor may be roughly classified into a charge coupled device (CCD) image sensor and a complementary metal oxide semiconductor (CMOS) image sensor (CIS).

During the fabrication of image sensors, a photodiode may be formed in a substrate using ion implantation. As the size of a photodiode is reduced for the purpose of increasing the number of pixels without increasing chip size, the area of a light receiving portion is also reduced, thereby resulting in a reduction in image quality.

Also, since a stack height does not reduce as much as the reduction in the area of the light receiving portion, the number of photons incident to the light receiving portion is also reduced due to diffraction of light called. Airy disk.

As an alternative to overcome this limitation, an attempt of forming a photodiode using amorphous silicon (Si), or forming a readout circuitry in a silicon (Si) substrate using a method such as wafer-to-wafer bonding and forming a photodiode on and/or over the readout circuitry has been made (referred to as a “three-dimensional (3D) image sensor”). The photodiode is connected with the readout circuitry through a metal interconnection.

In a manufacture of a 3D image sensor according to a related-art, there are difficulties in performing a wafer-to wafer alignment between a photodiode positioned at an upper part of a chip and a readout circuit unit formed at a silicon substrate, and ensuring an ohmic contact due to a poor contact between an interconnection of the readout circuit and the photodiode.

According to a related-art, a via plug electrically connecting the photodiode to the readout circuitry is present within the light receiving portion of the photodiode, thereby reducing a fill factor.

In addition, since both the source and the drain of the transfer transistor are heavily doped with N-type impurities in a related art, a charge sharing phenomenon occurs. When the charge sharing phenomenon occurs, the sensitivity of an output image is reduced and an image error may be generated. Also, because a photo charge does not readily move between the photodiode and the readout circuitry, a dark current is generated and/or saturation and sensitivity is reduced.

### BRIEF SUMMARY

Embodiments provide an image sensor and a method for manufacturing the same, which do not require a wafer-to-wafer alignment for connection between an image sensing device at an upper part of the image sensor and a readout circuitry, while acquiring an ohmic contact between an interconnection of the readout circuitry and the image sensing device.

Embodiments also provide an image sensor and method for manufacturing the same, which can improve a fill factor by forming a via plug at a pixel boundary for electrically connecting an image sensing device and a readout circuitry.

Embodiments also provide an image sensor and a method for manufacturing the same, which can increase a fill factor without a charge sharing phenomenon.

Embodiments also provide an image sensor that can minimize a dark current source and inhibit saturation reduction and sensitivity degradation by forming a smooth transfer path of photo charges between an image sensing device and a readout circuit, and a method for manufacturing the same.

In one embodiment, an image sensor comprises: a readout circuitry in a first substrate; an interconnection over the first substrate and electrically connected to the readout circuitry; an image sensing device over the interconnection; and a via plug at a pixel boundary for electrically connecting the image sensing device and the interconnection.

In another embodiment, a method for manufacturing an image sensor comprises: forming a readout circuitry in a first substrate; forming an interconnection over the first substrate and electrically connected to the readout circuitry; forming an image sensing device over the interconnection; and forming a via plug at a pixel boundary for electrically connecting the image sensing device and the interconnection.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of an image sensor according to an embodiment.

FIGS. 2-10 are cross-sectional views of a method for manufacturing an image sensor according to a first embodiment.

FIG. 11 is a plan view of an image sensor according to an embodiment.

FIG. 12 is a cross-sectional view of an image sensor according to a second embodiment.

### DETAILED DESCRIPTION

Hereinafter, embodiments of an image sensor and a method for manufacturing the same will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

FIG. 1 is a cross-sectional view of an image sensor according to an embodiment.

Referring to FIG. 1, an image sensor can include: a first substrate 100 having readout circuitry (not shown); an interconnection 150 over the first substrate 100 and electrically connected to the readout circuitry; an image sensing device 210 over the interconnection 150; and a via plug 250 at a pixel boundary for electrically connecting the image sensing device 210 and the interconnection 180.

The image sensing device 210 may be a photodiode, but, without being limited thereto, may be a photogate, or a combination of the photodiode and the photogate. Embodiments include an image sensing device 210 formed in a crystalline semiconductor layer as an example. However, embodiments are not limited thereto, and may include a photodiode formed in amorphous semiconductor layers.

Unexplained reference numerals in FIG. 1 will be described with reference to the drawings illustrating a method for manufacturing the image sensor below.

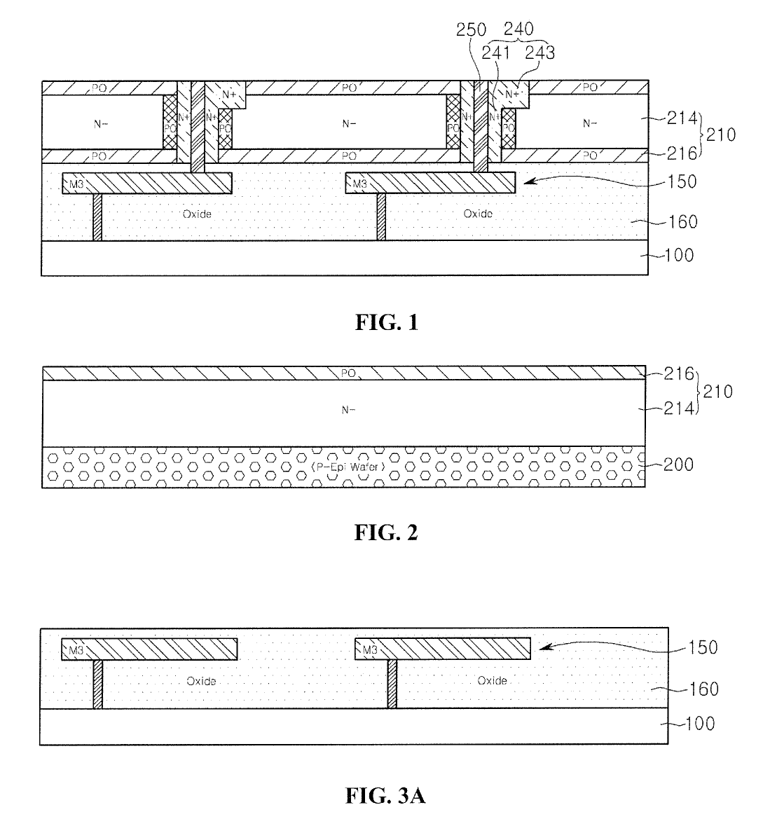

Hereinafter, a method for manufacturing an image sensor according to a first embodiment will be described with reference to FIGS. 2 through 10.

As shown in FIG. 2, an image sensing device 210 is formed on a second substrate 200. For example, a photodiode 210 including a P-type conductive layer 216, and a low-concentration N-type conductive layer 214 may be formed by implanting ions into a crystalline semiconductor layer, but embodiments are not limited thereto.

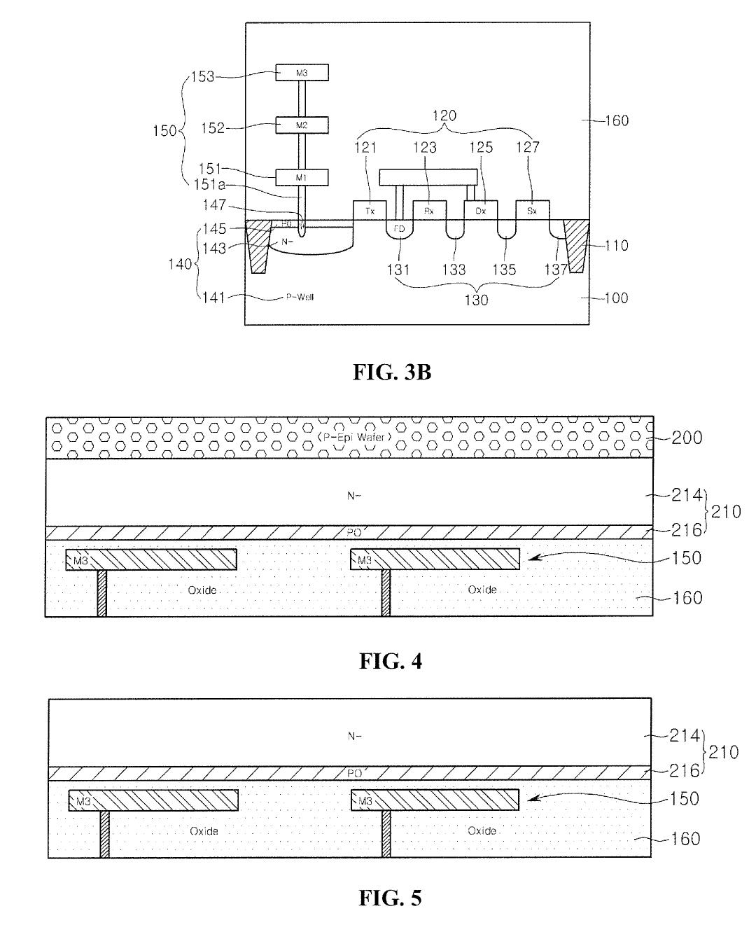

As shown in FIGS. 3A and 3B, a first substrate 100 where an interconnection 150 and a readout circuitry 120 are formed is prepared. FIG. 3B is a detailed view illustrating the first substrate 100 where the interconnection 150 and the readout circuitry 120 are formed.

Referring to FIG. 3B, the first substrate 100 including the interconnection 150 and the readout circuitry 120 is prepared. For example, an active region is defined by forming a device isolation layer 110 in the second conductive type first substrate 100. The readout circuitry 120 including a transistor is formed in the active region. For example, the readout circuitry 120 may include a transfer transistor (Tx) 121, a reset transistor (Rx) 123, a drive transistor (Dx) 125, and a select transistor (Sx) 127. An ion implantation region 130 including a floating diffusion region 131 and source/drain regions 133, 135 and 137 for each transistor may be formed.

The forming of the readout circuitry 120 in the first substrate 100 may include forming an electrical junction region 140 in the first substrate 100, and forming a first conductive type connection 147 connected to the interconnection 150 at an upper part of the electrical junction region 140.

For example, the electrical junction region 140 may be a P-N junction 140, but is not limited thereto. For example, the electrical junction region 140 may include a first conductive type ion implantation layer 143 formed on a second conductive type well 141 or a second conductive type epitaxial layer, and a second conductive type ion implantation layer 145 formed on the first conductive type ion implantation layer 143. For example, as shown in FIG. 3B, the P-N junction 140 may be a P0(145)/N−(143)/P−(141) junction, but is not limited thereto. The first substrate 100 may be a second conductive type, but is not limited thereto.

According to an embodiment, the device is designed to provide a potential difference between the source and drain of the transfer transistor (Tx), thus implementing the full dumping of a photo charge. Accordingly, a photo charge generated in the photodiode is dumped to the floating diffusion region, thereby increasing the output image sensitivity.

That is, referring to FIG. 3B, the embodiment forms the electrical junction region 140 in the first substrate 100 including the readout circuit 120 to provide a potential difference between the source and drain of the transfer transistor (Tx) 121, thereby implementing the full dumping of a photo charge.

Thus, unlike the related art case of connecting a photodiode simply to an N+ junction, the embodiment makes it possible to inhibit saturation reduction and sensitivity degradation.

Thereafter, a first conductive type connection 147 is formed between the photodiode and the readout circuit to create a smooth transfer path of a photo charge, thereby making it possible to minimize a dark current source and inhibit saturation reduction and sensitivity degradation.

To this end, the first embodiment may form a first conductive type connection 147 for an ohmic contact on the surface of the P0/N−/P− junction 140. The N+ region (147) may be formed such that it pierces the P0 region (145) to contact the N− region (143).

The width of the first conductive type connection 147 may be minimized to inhibit the first conductive type connection 147 from being a leakage source. To this end, a plug implant may be performed after etching a contact hole for a first metal contact 151a, but embodiments are not limited thereto. For example, an ion implantation pattern (not shown) may be formed by another method, and the implantation pattern may be used as an ion implantation mask to form the first conductive type connection 147.

That is, a reason why an N+ doping is performed only on a contact formation region is to minimize a dark signal and help the smooth formation of an ohmic contact. If the entire Tx source region is N+ doped like the related art, a dark signal may increase due to an Si surface dangling bond.

Next, an interlayer dielectric 160 may be formed on the first substrate 100, and an interconnection 150 may be formed. The interconnection 150 may include the first metal contact 151a, a first metal 151, a second metal 152, and a third metal 153, but embodiments are not limited thereto.

Next, as shown in FIG. 4, the second substrate 200 where the image sensing device 210 is formed is bonded over the interconnection, and the second substrate 200 is removed to leave the image sensing device 210 above the interconnection 150, as shown in FIG. 5.

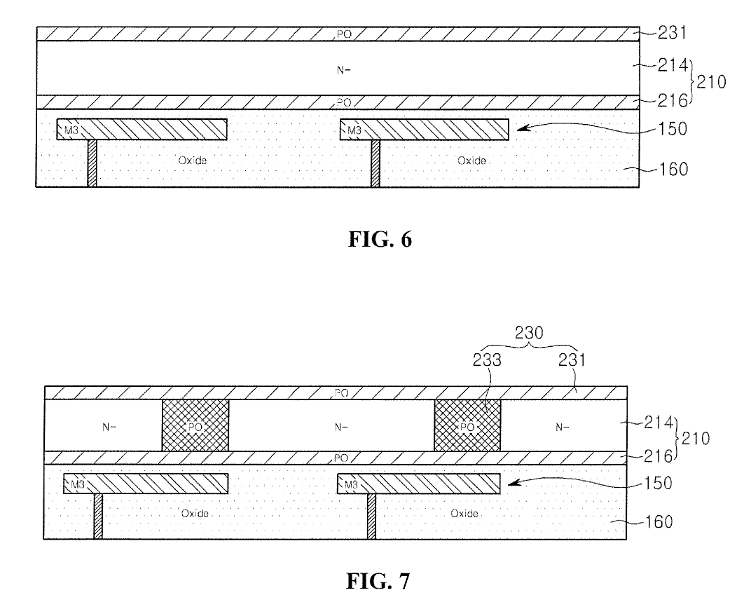

Next, as shown in FIG. 6, a second conductive type ion implantation region 231 is formed on the exposed image sensing device 210. For example, a P0 implant may be performed on the surface of the photodiode at an upper part of the chip. The second conductive type ion implantation region 231 may serve as a device isolation and bias layer.

Next, as shown in FIG. 7, a second conductive type ion implantation device isolation region 233 is formed at a pixel boundary of the image sensing device 210. For example, a P0 region 233 may be formed for pixel-to-pixel isolation using a photolithography process (to create an implant mask) and an ion implantation process. The second conductive type ion implantation region 231 and the second conductive type ion implantation device isolation region 233 may serve as a device isolation region 230.

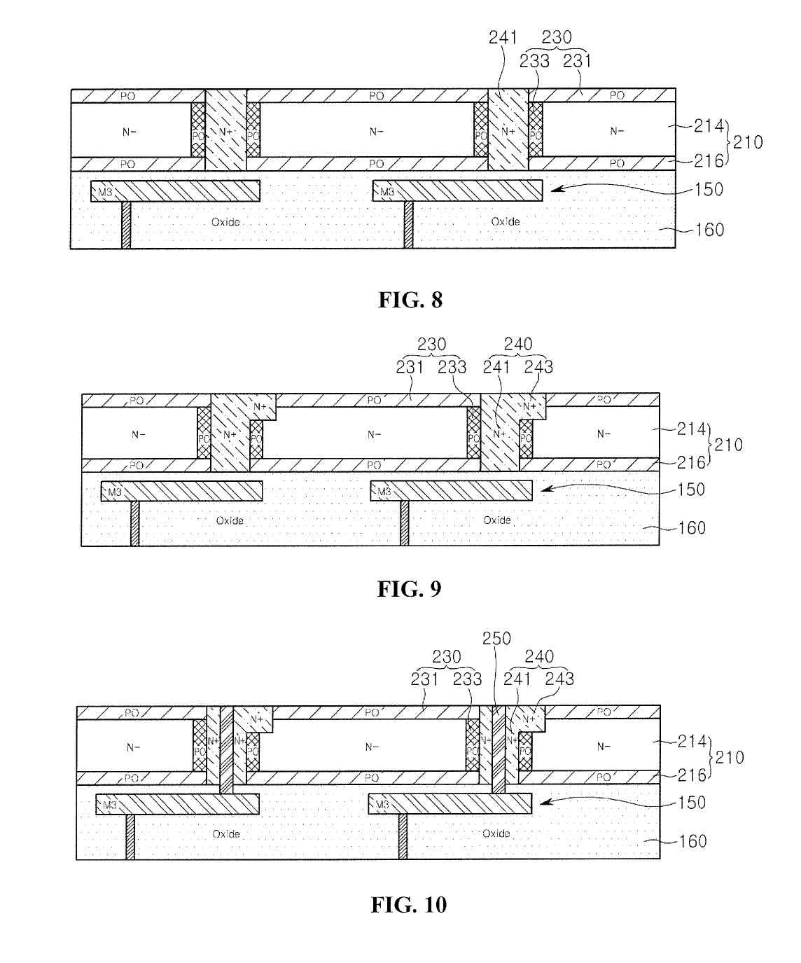

Next, as shown in FIG. 8, a first conductive type first ion implantation region 241 is formed in the second conductive type ion implantation device isolation region 233. For example, a first N+ region 241 may be formed for connection between the photodiode 210 at an upper part of the chip and a readout circuit unit 120 of a silicon substrate using a photolithography process (to create an implant mask) and an ion implantation process.

Next, as shown in FIG. 9, a first conductive type second ion implantation region 243 is formed to electrically connect the image sensing device 210 and the first conductive type first ion implantation region 241. For example, a second N+ region 243 may be formed to electrically connect the first conductive type first ion implantation region 241 and the image sensing device 210 for connection of the photodiode 210 at the upper part of the chip and the readout circuit unit 120 of the silicon substrate using a photolithography process (to create an implant mask) and an ion implantation process. The first conductive type first ion implantation region 241 and the first conductive type second ion implantation region 243 may become a first conductive type via connection region 240.

The ion-implanted layers formed after bonding the photodiode 210 to the first substrate are activated through a heat treatment such as a laser anneling.

Next, as shown in FIG. 10, a via plug 250 is formed through the first conductive type first ion implantation region 241 to be electrically connected to the interconnection 150. For example, the via plug 250 is formed at pixel boundaries in a hole formed in the photodiode 210 at the upper part of the chip. The via plug 250 can be used to apply a voltage to the photodiode 210 and deliver photocharges to the readout circuitry 120 of the silicon substrate.

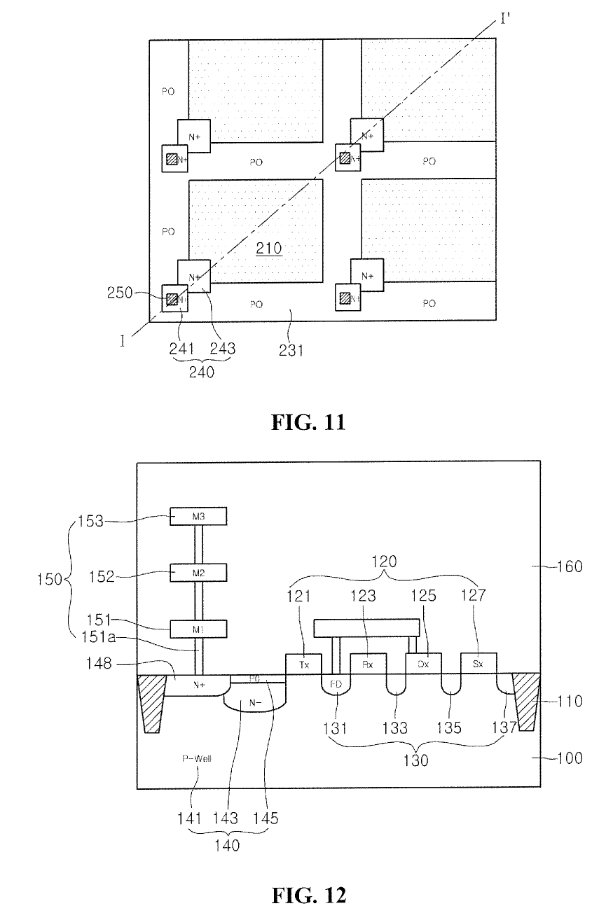

FIG. 11 is a plan view of the image sensor according to an embodiment.

According to an embodiment, processes are efficiently performed without a wafer-to-wafer alignment for connection of the image sensing device and the readout circuitry. Also, a voltage can be applied to the image sensing device through a process of forming a via plug connected to the interconnection after performing an N+ ion implantation (to form region 240), thereby acquiring an ohmic contact between the interconnection of readout circuitry and the image sensing device.

Also, according to an embodiment, a fill factor may be improved by forming the via plug electrically connecting the image sensing device and the readout circuitry at the pixel boundary.

FIG. 12 is a cross-sectional view of an image sensor according to a second embodiment specifically illustrating a detailed view of a first substrate where an interconnection is formed.

An image sensor according to the second embodiment can include the features described with respect to FIG. 1 such as: a readout circuitry in a first substrate; an interconnection over the first substrate and electrically connected to the readout circuitry; an image sensing device over the interconnection; and a via plug at a pixel boundary for electrically connecting the image sensing device and the interconnection.

The second embodiment may adopt the technical features of the first embodiment.

However, differently from the first embodiment, a first conductive type connection 148 is formed at one side of the electrical junction region 140.

An N+ connection region 148 may be formed at a P0/N−/P− junction 140 to provide an ohmic contact. The process of forming an N+ connection region and a first metal contact 151a may provide a leakage source. This is because an electric field (EF) may be generated over the Si surface due to operation while a reverse bias is applied to the P0/N−/P− junction 140. A crystal defect generated during the contact forming process inside the electric field may become a leakage source.

Also, when the N+ connection region (see reference 147 of FIG. 3B) is formed over the surface of P0/N−/P− junction 140, an electric field may be additionally generated due to the N+/P0 junction. This electric field may also become a leakage source.

Therefore, the second embodiment proposes a layout in which first contact plug 151a is formed in an active region not doped with a P0 layer but including N+ connection region 148 that is electrically connected to N− junction 143.

According to the second embodiment, the electric field is not generated on and/or over the Si surface, thereby contributing to reduction in a dark current of a 3D integrated CIS.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a readout circuitry in a first substrate;
an interconnection over the first substrate and electrically connected to the readout circuitry;
an image sensing device over the interconnection; and
a via plug at a pixel boundary electrically connecting the image sensing device and the interconnection.

2. The image sensor according to claim 1, further comprising a second conductive type ion implantation device isolation region at the pixel boundary of the image sensing device,
wherein the via plug is electrically connected to the interconnection through the second conductive type ion implantation device isolation region.

3. The image sensor according to claim 2, further comprising:
a first conductive type first ion implantation region in the second conductive type ion implantation device isolation region; and
a first conductive type second ion implantation region electrically connecting the image sensing device and the first conductive type first ion implantation region,
wherein the via plug penetrates through the first conductive type first ion implantation region.

4. The image sensor according to claim 1, further comprising an electrical junction region at the first substrate and electrically connected to the readout circuitry.

5. The image sensor according to claim 4, further comprising a first conductive type connection between the electrical junction region and the interconnection to electrically connect the interconnection and the electrical junction region.

6. The image sensor according to claim 5, wherein the readout circuitry comprises a transistor, wherein the electrical junction region is disposed at a source of the transistor to provide a potential difference between the source and a drain of the transistor.

7. A method for manufacturing an image sensor, comprising:
forming a readout circuitry in a first substrate;
forming an interconnection over the first substrate and electrically connected to the readout circuitry;
forming an image sensing device over the interconnection; and
forming a via plug at a pixel boundary for electrically connecting the image sensing device and the interconnection.

8. The method according to claim 7, further comprising:
forming a second conductive type ion implantation device isolation region at the pixel boundary of the image sensing device;
wherein the forming of the via plug at the pixel boundary comprises forming the via plug electrically connected to the interconnection through the second conductive type ion implantation device isolation region.

9. The method according to claim 8, further comprising:
forming a first conductive type first ion implantation region in the second conductive type ion implantation device isolation region; and
forming a first conductive type second ion implantation region electrically connecting the image sensing device and the first conductive type first ion implantation region,
wherein the via plug contacts the first conductive type first ion implantation region.

10. The method according to claim 7, further comprising forming an electrical junction region at the first substrate and electrically connected to the readout circuit.

11. The method according to claim 10, further comprising forming a first conductive type connection between the electrical junction region and the interconnection to electrically connect the interconnection and the electrical junction region.

12. The method according to claim 11, wherein the first conductive type connection is formed at an upper part of the electrical junction region.

13. The method according to claim 11, wherein the forming of the first conductive type connection is performed after a contact etch for the interconnection.

14. The method according to claim 11, wherein the first conductive type connection is formed at one side of the electrical junction region.

15. The method according to claim 10, wherein an ion implantation concentration of the electrical junction region is smaller than an ion implantation concentration of a floating diffusion region of the readout circuitry.
